(19) United States
(12) Patent Application Publication
(10) Pub. No.: US 2025/0329529 A1
(43) Pub. Date: Oct. 23, 2025

(54) VOLUMETRIC EXPANSION DEPOSITION OF SILICON BASED DIELECTRIC FILM

(71) Applicant: Applied Materials, Inc., Santa Clara, CA (US)

(72) Inventors: Bhaskar SOMAN, Santa Clara, CA (US); Supriya GHOSH, San Jose, CA (US); Yanze WU, Santa Clara, CA (US); Sukrant DHAWAN, Santa Clara, CA (US); Susmit SINGHA ROY, Mountain View, CA (US); Akhil SINGHAL, Portland, OR (US); Abhijit B. MALLICK, Fremont, CA (US)

(21) Appl. No.: 18/643,462

(22) Filed: Apr. 23, 2024

(51) Int. Cl. H01L 21/02; H01J 37/32

(52) U.S. Cl. CPC H01L 21/02164; H01J 37/32449; H01L 21/02274; H01L 21/0262; H01J 2237/3321

(57) ABSTRACT

The present disclosure provides methods. The methods include forming a precursor film by delivering a precursor to a substrate in a processing chamber having a high aspect ratio opening defining a gap between two or more features of the substrate. An expansion film is formed by treating the precursor film with a plasma. An oxygen-containing compound is delivered to the expansion film to form an oxide gap fill material having a volume that is about 1.1 to about 2.0 greater than an expansion film.

### BACKGROUND

### Field

Embodiments of the present disclosure generally relate to a method of forming high aspect ratio features that are substantially free of voids and seams.

### Description of the Related Art

Memory devices achieve increased capacity by density scaling which involves stacking memory cells vertically in layers. These high aspect ratio structures pose various processing challenges particular in large area gap fill. Currently, large area gap fill is done using plasma enhanced chemical vapor deposition processes to deposit silicon-containing films. Conventional PECVD processes tend to create seam and void challenges in addition to conformality challenges. The silicon-containing films are subsequently etched to form memory openings which are filled with conductive metals to form connections. Forming the connections can cause cracking and other defects which can be problematic in downstream processes.

Therefore there is a need for large area gap fill processes and chemistry that enables high throughput and high quality devices having structure that are substantially free of voids and seams.

### SUMMARY

The present disclosure provides methods. The methods include forming a precursor film by delivering a precursor to a substrate in a processing chamber having a high aspect ratio opening defining a gap between two or more features of the substrate. An expansion film is formed by treating the precursor film with a plasma. An oxygen-containing compound is delivered to the expansion film to form an oxide gap fill material having a volume that is about 1.1 to about 2.0 greater than the expansion film.

The present disclosure also provides methods. The methods include forming a precursor film by delivering a precursor to a substrate in a processing chamber having a high aspect ratio opening defining a gap between two or more features of the substrate. An expansion film is formed by treating the precursor film with a plasma. The plasma and the precursor are alternated cyclically to form the expansion film. An oxygen-containing compound is delivered to the expansion film to form an oxide gap fill material having a volume that is about 1.1 to about 2.0 greater than the expansion film. The oxygen-containing compound and the formation of the expansion film are alternated cyclically to form the oxide gap fill material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a process flow diagram of a method according to some embodiments described herein.

FIGS. 2A-2D are illustrative schematics of a memory device, according to some embodiments described herein. FIG. 2A shows a substrate having a precursor film disposed on a surface of the substrate. FIG. 2B shows a substrate having an expansion film disposed on a surface of the substrate. FIG. 2C shows a substrate having an oxide gap fill material disposed on a surface of the substrate. FIG. 2D shows a substrate having a gap filled with an oxide gap fill material.

FIG. 3 shows images of a memory device produced by a conventional deposition process compared to a volumetric expansion deposition process, according to some embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Recently, high density storage devices have been developed that include a three-dimensional (3D) stacked memory structure. For example, a 3D NAND stacked memory device can be formed from an array of alternating vertical stacks of dielectric materials and electrically conductive layers. A large area, high aspect ratio opening is formed during the production of the alternating vertical stacks, where a gap separates two or more vertical stacks. In some embodiments, the large area, high aspect ratio opening has a depth of about 10 μm to about 15 μm and a width of about 1 μm to about 2 μm. In some embodiments, the aspect ratio of the opening is about 5:1 to about 50:1, such as about 10:1 to about 20:1. The high aspect ratio opening is filled with a dielectric material, such as a silicon-containing material, e.g., silicon oxide.

Filling large areas (e.g., large area gap fill) with the silicon-containing material can form voids and seams which can cause quality issues for memory devices in downstream processing, such as cracking and shrinking. The processes described herein improve large area gap fill, while reducing potential of shrinkage and stress, as well has enhancing film quality. The methods described herein deposit silicon-containing material, such as silicon based dielectric films using a silicon based compound, e.g., silicon, silicon carbide, silicon carbon-nitride, silicon oxycarbonitride, silicon nitride, or combinations thereof in an atomic layer deposition process at temperatures of less than 400° C., followed by oxidation of the silicon based compound to form an oxide. In particular, 3D NAND structures can be formed by stacking alternating films and forming channels through the stack of alternating films. Conventional methods of filling the high aspect ratio openings with a silicon-containing material includes using plasma enhanced chemical vapor deposition (PECVD) processes. The film deposited in a conventional manner typically has a tensile property which causes cracking in the device after subsequent processing, such as during etching and metal connection formation. It has been discovered that the chemistry and use of atomic layer deposition (ALD) described herein enables deposition of film having compressive properties and less prone to cracking. The resulting device maintains structural integrity after further processing.

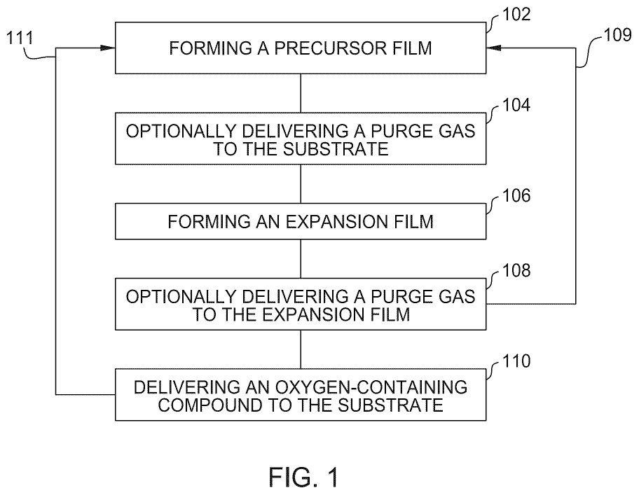

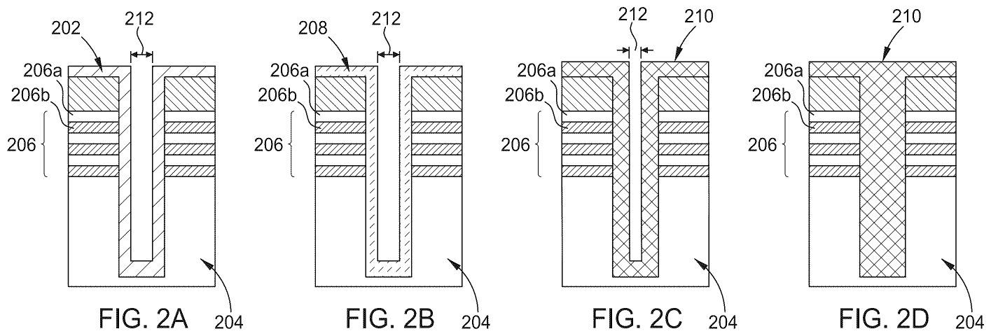

Now referring to FIG. 1, a process flow diagram of an example method 100 according to some embodiments is shown. The method 100 includes, at operation 102, a precursor film 202 is formed on a substrate 204 in a processing chamber, such as an atomic layer deposition chamber available from Applied Materials of Santa Clara, CA. A precursor film 202 may be formed by delivering a precursor to a substrate, as shown in FIG. 2A. In some embodiments which can be combined with other embodiments, the precursor includes a dielectric precursor. A dielectric precursor can include an organosilicon compound, e.g., a compound having silicon, hydrogen, and/or a combination thereof such as silane. A substrate, for example, may be a metal substrate, such as aluminum or stainless steel, a semiconductor substrate, such as silicon, silicon-on-insulator (SOI), or gallium arsenide, a glass substrate, or a plastic substrate. A semiconductor substrate may be a patterned substrate at any stage of manufacture/fabrication in the formation of integrated circuits. The patterned substrate may include one or more features, e.g., gaps, trenches, holes, vias, fins, columns, film stacks, layers, films, or other structures disposed on the substrate, that are to be filled with dielectric material. For example, the patterned substrate can include a gap 212, as shown in FIG. 2A. For example, the features can be or include a plurality of fins, where each fin contains a film stack 206. The film stack 206 can include alternating pairs of layers disposed on one another 206a and 206b. In one or more examples, each of the pairs of layers contains silicon-germanium layers and silica layers. Each of the silicon-germanium layers and silica layers can independently be deposited or formed by an epitaxial growth process or an atomic layer deposition (ALD) process.

In one or more embodiments which can be combined with other embodiments, the features can be or include a plurality of silicon-germanium/silicon (SiGe/Si) fin structures or a plurality of germanium/silicon (Ge/Si) fin structures. In some examples, each of the SiGe layers, the Si layers, or the Ge layers has a thickness of about 5 nm to about 30 nm, such as about 5 nm, about 8 nm, or about 10 nm to about 12 nm, about 15 nm, about 20 nm, about 25 nm, or about 30 nm.

In an embodiment which can be combined with other embodiments, the substrate can include a high aspect ratio opening. A high aspect ratio opening can include gaps, trenches, holes, vias, fins, columns, film stacks, layers, films, or other structures disposed on the substrate having a depth of about 10 μm to about 15 μm and a width of about 1 μm to about 2 μm. In some embodiments, the aspect ratio of the opening is about 5:1 to about 50:1, such as about 10:1 to about 20:1. The high aspect ratio opening can be filled with a dielectric material, such as a silicon-containing material.

The precursor can be delivered to the substrate for about 200 milliseconds (ms) to about 1200 ms, e.g., about 200 ms to about 400 ms, about 400 ms to about 600 ms, about 600 ms to about 800 ms, about 800 ms to about 1000, or about 1000 ms to about 1200 ms. In an embodiment, the precursor 202 can be pulsed, where the precursor may be delivered for a first period of time of about 200 ms to about 1200 ms, followed by a second period of time of about 200 ms to about 1200 ms. The precursor 202 can be delivered to the substrate 204 to provide a concentration of the precursor 202 on the substrate of about 350 mg/m to about 1400 mg/m, e.g., about 350 mg/m to about 500 mg/m, about 500 mg/m to about 1000 mg/m, or about 1000 mg/m to about 1400 mg/m. In an embodiment, the precursor 202 can be delivered to the substrate 204 at a flow rate of about 1500 sccm to about 2500 sccm, e.g., about 1500 sccm to about 1600 sccm, about 1600 sccm to about 1700 sccm, about 1700 sccm to about 1800 sccm, about 1800 sccm to about 1900 sccm, about 1900 sccm to about 2000 sccm, about 2000 sccm to about 2100 sccm, about 2100 sccm to about 2200 sccm, about 2200 sccm to about 2300 sccm, about 2300 sccm to about 2400 sccm, or about 2400 sccm to about 2500 sccm.

In an embodiment, the precursor can be delivered to the substrate 204 using a carrier gas, e.g., argon, hydrogen, helium, or a combination thereof. In an embodiment, a flow ratio of about 1:100 to about 1:500 of dielectric precursor to carrier gas, e.g., about 1:100 to about 1:125, about 1:125 to about 1:166, or about 1:166 to about 1:500.

In an embodiment, delivering the precursor to the substrate 204 can include maintaining a temperature of the processing chamber at about 350° C. to about 400° C., e.g., about 350° C. to about 360° C., about 360° C. to about 370° C., about 370° C. to about 380° C., about 380° C. to about 390° C., or about 390° C. to about 400° C. Without being bound by theory, a temperature of about 350° C. to about 400° C. allows for lower temperature processing to be implemented, increasing processability. The processing chamber can be maintained at a pressure of about 1 Torr to about 20 Torr, e.g., about 1 Torr to about 5 Torr, about 5 Torr to about 10 Torr, about 10 Torr to about 15 Torr, or about 15 Torr to about 20 Torr.

In an embodiment, the precursor may be deposited to form a precursor film 202 on the substrate 204, as shown in FIG. 2B. In an embodiment, the monolayer of the precursor 202 can be about 1.5 Å to about 10 Å, e.g., about 1.5 Å to about 3 Å, about 3 Å to about 5 Å, about 5 Å to about 7 Å, about 7 Å to about 9 Å, or about 8 Å to about 10 Å.

At operation 104, a purge gas may be delivered to the substrate. The purge gas can include a nonreactive gas, e.g., a nitrogen-containing gas such as diatomic nitrogen, an argon-containing gas such as argon, or a helium-containing gas, such as helium. In an embodiment, the purge gas may be delivered to the substrate at a flow rate of about 1500 sccm to about 2500 sccm, e.g., about 1500 sccm to about 1600 sccm, about 1600 sccm to about 1700 sccm, about 1700 sccm to about 1800 sccm, about 1800 sccm to about 1900 sccm, about 1900 sccm to about 2000 sccm, about 2000 sccm to about 2100 sccm, about 2100 sccm to about 2200 sccm, about 2200 sccm to about 2300 sccm, about 2300 sccm to about 2400 sccm, or about 2400 sccm to about 2500 sccm. In some embodiments, the purge gas can be supplied to the substrate between each pulse of the precursor 202 during operation 102.

At operation 106, an expansion film 208 is produced by treating the precursor film 202 with a plasma, as shown in FIG. 2B. The expansion film 208 can include one or more a silicon-based film, e.g., silicon, silicon carbide, silicon carbon-nitride, silicon oxycarbonitride, silicon nitride, or combinations thereof. For example, the expansion film 208 can include a silicon film. As a further example, the expansion film 208 can include a silicon carbon nitride film or a silicon nitride film. In some embodiments, the deposited expansion film 208 can have a film conformality of about 90% to about 100%, e.g., about 90% to about 92%, about 92% to about 94%, about 94% to about 96%, about 96% to about 98%, or about 98% to about 100%, where the film conformality is a ratio between the thickness of the top sidewall of the trench and the bottom sidewall of the trench multiplied by 100.

In an embodiment, the expansion film can include a Pilling-Bedworth ratio of about 1.0 to about 2.0, e.g., about 1.0 to about 1.2, about 1.2 to about 1.4, about 1.4 to about 1.6, about 1.6 to about 1.8, or about 1.8 to about 2.0, where a Pilling-Bedworth ratio is the ratio of volume change due to the formation of an oxide. For example, a silicon carbon nitride film can include a Pilling-Bedworth ratio of about 1.5 to about 1.6. As a further example, a silicon film can include a Pilling-Bedworth ratio of about 2.0. Without being bound by theory an expansion film having a higher Pilling-Bedworth ratio may be advantageous due to the increased volumetric expansion of the expansion film when forming the oxide layer, reducing and/or eliminating a seam formed during gap filling.

In an embodiment, one or more radicals (also referred to as reactive gas), and/or charged ions are produced by the plasma and introduced to the processing chamber to produce the expansion film 208. The plasma may be generated in a remote plasma source (RPS) outside the processing chamber. The radicals may be flowed into the processing chamber along with a carrier gas (e.g., Ar, He). The plasma can be generated by the dissociation of a gas including a carbon compound (e.g., C₁-C₆ alkyl, C₁-C₆ alkylene, C₁-C₆ alkynl, C—X, where X is a halide), nitrogen compound, (e.g., N₂), a nitrogen-hydrogen compound (e.g., NH₃, N₂H₄), nitrogen-carbon compound (e.g., CN, OCN,) or a combination thereof. In the plasma, C* and/or N*-containing radicals may be activated, such as C*, CN*, OCN*, N*, NH₃*, N₂H₄*, NH₂*, NH*, C₃H₆*, C₂H₂*, or a combination thereof.

In some embodiments, the radicals activated in the RPS are flowed into the processing chamber (referred to as “radical flux”) at a flow rate between about 1 sccm and about 10000 sccm. The composition of the expansion film 208 can be adjusted by changing the composition of the reactive gas in the radical flux. To form a nitrogen-containing film, such as SiCN, SiOCN, and SiN films, the reactive gas may be, for example, cyanide (CN), ammonia (NH₃), hydrogen (H₂), hydrazine (N₂H₄), nitrogen dioxide (NO₂), or nitrogen (N₂). To form a carbon-containing film, such as SiC, the reactive gas may be, for example, C₁-C₆ alkyl, C₁-C₆ alkylene, C₁-C₆ alkynl, C—X, where X is a halide.

The plasma in the RPS can have a power of about 100 watts (W) to about 2000 W, e.g., about 100 W to about 500 W, about 500 W to about 1000 W, about 1000 W to about 1500 W, or about 1500 W to about 2000 W, when operating at a frequency of about 100 KHz to about 50 MHz, e.g., about 100 KHz to about 1 MHz, about 1 MHz to about 10 MHz, about 10 MHz to about 30 MHz, or about 30 MHz to about 50 MHz, during the plasma treatment. In an embodiment, the reactive gas in the radical flux can be exposed to the plasma for a period of about 0.1 s to about 10 s, e.g., about 0.1 s to about 1 s, about 1 s to about 3 s, about 3 s to about 5 s, about 5 s to about 7 s, about 7 s to about 9 s, or about 8 s to about 10 s. In an embodiment, the plasma can be pulsed, where the plasma is pulsed for a first period of time of about 0.1 s to about 9 s at a frequency of about 200 Hz to about 1000 Hz, followed by a second period of time of about 0.1 s to about 9 s at a frequency of about 200 Hz to about 1000 Hz. Without wishing to be bound by theory, by treating the precursor film with the plasma, having varying plasma conditions, to produce an expansion film, a variety of precursors can be implemented, reducing the complexity of volumetric expansion deposition processes. Additionally, and without wishing to be bound by theory, the use of the plasma treatment can increase conformality of the expansion film, promoting the reduction and/or elimination of seam formation in the gap.

At operation 108, a purge gas may be delivered to the expansion film 208. The purge gas can include a nonreactive gas, e.g., a nitrogen-containing gas such as diatomic nitrogen, an argon-containing gas such as argon, or a helium-containing gas, such as helium. In an embodiment, the purge gas may be delivered to the substrate at a flow rate of about 1500 sccm to about 2500 sccm, e.g., about 1500 sccm to about 1600 sccm, about 1600 sccm to about 1700 sccm, about 1700 sccm to about 1800 sccm, about 1800 sccm to about 1900 sccm, about 1900 sccm to about 2000 sccm, about 2000 sccm to about 2100 sccm, about 2100 sccm to about 2200 sccm, about 2200 sccm to about 2300 sccm, about 2300 sccm to about 2400 sccm, or about 2400 sccm to about 2500 sccm. In some embodiments, the purge gas can be supplied to the expansion film 208 between each pulse of the plasma during operation 106.

In an embodiment, the set of operations (e.g. operations 102-108) may be repeated for multiple cycles according to operation 109. In an embodiment, by repeating each of the set of operations, e.g., operations 102-108, a thicker expansion film 208 may be formed. In an embodiment, each set of operations (e.g. operations 102-108) can provide an expansion film deposition growth per cycle, e.g., operation 109, of about 1.5 Å per cycle to about 3 Å per cycle, e.g., about 1.5 Å per cycle to about 2.0 Å per cycle, about 2.0 Å per cycle to about 2.5 Å per cycle, or about 2.5 Å per cycle to about 3.0 Å per cycle.

At operation 110, the method includes delivering an oxygen-containing compound to the substrate. In some embodiments, the oxygen-containing compound is an oxygen-containing plasma that is delivered from an RPS. The oxygen-containing compound can include one or more compounds capable of oxidizing the expansion film 208. For example, the oxygen-containing compound can include O₂ (e.g., diatomic oxygen), O₃ (e.g., ozone), H₂O₂ (e.g., peroxide), H₂O (e.g., water), N₂O (e.g., nitrous oxide), oxygen plasma, or combinations thereof.

In an embodiment, the oxygen-containing compound is oxygen (O₂) gas and is provided to the RPS at a flow rate of about 1000 sccm to about 3000 sccm, e.g., about 1000 sccm to about 1500 sccm, about 1500 sccm to about 2000 sccm, about 2000 sccm to about 2500 sccm, or about 2500 sccm to about 3000 sccm. In some embodiments, the oxygen-containing compounds is delivered to the substrate using a carrier gas. The carrier gas may be delivered to the substrate with the oxygen-containing compound at a flow rate of about 0 sccm to about 3000 sccm, e.g., about 0 sccm to about 500 sccm, about 500 sccm to about 1000 sccm, about 1000 sccm to about 1500 sccm, about 1500 sccm to about 2000 sccm, about 2000 sccm to about 2500 sccm, or about 2500 sccm to about 3000 sccm. Without being bound by theory, delivering the oxygen-containing compound from the remote plasma source can improve film quality and reduce seams within the filled gap.

In an embodiment, the oxygen-containing compound is delivered to the substrate to produce a partial pressure of about 1% v/v to about 100% v/v of the oxygen-containing compound in the processing chamber, e.g., about 1% v/v to about 10% v/v, about 10% v/v to about 20% v/v, about 20% v/v to about 30% v/v, about 30% v/v to about 40% v/v, about 40% v/v to about 50% v/v, about 50% v/v to about 60% v/v, about 60% v/v to about 70% v/v, about 70% v/v to about 80% v/v, about 80% v/v to about 90% v/v, or about 90% v/v to about 100% v/v.

In some embodiments, the oxygen-containing compound can be pulsed for about 2 seconds(s) to about 10 s, e.g., about 2 s to about 4 s, about 4 s to about 6 s, about 6 s to about 8 s, or about 8 s to about 10 s. In some embodiments, a time pulse ratio of precursor to oxygen-containing plasma is about 1:100 to about 1:2, such as about 1:20 to about 1:5, such as about 1:12 to about 1:8, such as about 1:10 to about 1:7. In some embodiments, delivering the oxygen-containing compound can include treating the substrate with a purge gas is between each pulse. The purge gas can include a nonreactive gas, e.g., a nitrogen-containing gas such as diatomic nitrogen, an argon-containing gas such as argon, or a helium-containing gas, such as helium. In an embodiment, the purge gas may be delivered to the substrate at a flow rate of about 1500 sccm to about 2500 sccm, e.g., about 1500 sccm to about 1600 sccm, about 1600 sccm to about 1700 sccm, about 1700 sccm to about 1800 sccm, about 1800 sccm to about 1900 sccm, about 1900 sccm to about 2000 sccm, about 2000 sccm to about 2100 sccm, about 2100 sccm to about 2200 sccm, about 2200 sccm to about 2300 sccm, about 2300 sccm to about 2400 sccm, or about 2400 sccm to about 2500 sccm.

The plasma in the RPS can be generated using a power of about 100 watts (W) to about 2000 W, e.g., about 100 W to about 500 W, about 500 W to about 1000 W, about 1000 W to about 1500 W, or about 1500 W to about 2000 W, when operating at a frequency of about 100 KHz to about 50 MHz, e.g., about 100 KHz to about 1 MHz, about 1 MHz to about 10 MHz, about 10 MHz to about 30 MHz, or about 30 MHz to about 50 MHz, during the plasma treatment. Without being bound by theory, by tuning the power and frequency applied to the plasma, such as using an increased power and frequency during treatment and oxidation, the gap of the substrate, being a high aspect ratio opening, may be filled by volumetric expansion of the expansion film 208 due to conversion to an oxide using the oxidizing agent.

In an embodiment, the oxygen-containing compound can oxidize the expansion film 208 to produce an oxide gap fill material 210 having a volume that is greater than the expansion film 208. The oxide film can include silica oxide. In an embodiment, the oxide gap fill material 210 can have a volume that is about 1.1 to about 2.0 greater than the volume of the expansion film 208, e.g., about 1.1 to about 1.3, about 1.3 to about 1.5, about 1.5 to about 1.7, about 1.7 to about 1.9, or about 1.8 to about 2.0. In an embodiment, the volume increase of the silica oxide may correlate to the Pilling-Bedworth ratio of the expansion film. Without being bound by theory, the oxygen-containing compound can react with the expansion film, where the oxygen can be incorporated to the expansion film increasing the volume of the expansion film to provide an oxide gap fill material that is greater in volume than the expansion film.

In an embodiment, the set of operations (e.g. operations 102-110) may be repeated for multiple cycles according to operation 111 to fill the high aspect ratio opening, such as in atomic layer deposition processes. In an embodiment, by repeating each of the set of operations, e.g., operations 102-110, a thicker oxide gap fill material 210 may be formed having a reduced and/or eliminated seam in the gap 212, as shown in FIG. 2D. In an embodiment the set of operations may be repeated according to operation 111 to provide an oxide material that fills a gap 212 of the substrate to produce a gap fill material that is substantially free of voids and/or seams. Without wishing to be bound by theory, a gap fill material that is substantially free of voids and/or seams may include increased acid etch resistivity, providing enhanced structural integrity after further processing as compared to conventional plasma enhanced chemical vapor deposition processes.

In some embodiments, the method 100 described herein enables depositing a gap fill material 210 to a thickness of about 500 nm to about 2 μm, e.g., about 500 nm to about 1 μm, about 1 μm to about 1.5 μm, or about 1.5 μm to about 2 μm, using about 2 cycles to about 4000 cycles, e.g., about 2 cycles to about 100 cycles, about 100 cycles to about 1000 cycles, about 1000 cycles to about 2000 cycles, about 2000 cycles to about 3000 cycles, or about 3000 cycles to about 4000 cycles. As used herein, a growth per cycle refers to a thickness deposited per cycle of operations 102-110. In some embodiments, the growth per cycle for a first duration is larger than a grown per cycle for a second duration after the first duration. In some embodiments, the precursor compounds, precursor flow rate, gas ratios, plasma powers, plasma frequencies, oxygen-containing compounds, oxygen-containing compound flow rates, or a combination thereof are adjusted to adjust growth per each cycle.

In an embodiment the gap fill material can include oxide gap fill material that can expand to produce a compressive strength of the gap fil material, reducing and/or eliminating a seam and/or void of the gap fill material. The stress can include a tensile stress of about 50 MPa to about 350 MPa, e.g., about 50 MPa to about 100 MPa, about 100 MPa to about 150 MPa, about 150 MPa to about 200 MPa, about 200 MPa to about 250 MPa, about 250 MPa to about 300 MPa, or about 300 MPa to about 350 MPa. The stress can include a compressive stress of about-350 MPa to about-100 MPa, e.g., about-350 MPa to about-300 MPa, about-300 MPa to about-250 MPa, about-250 MPa to about-200 MPa, about-200 MPa to about-150 MPa, or about-150 MPa to about-100 MPa. In an embodiment, the gap fill material can include high conformality and low shrinkage, due to the expansive properties of the gap fill material.

Overall, the methods described herein enable large area gap fill for 3D NAND devices at temperatures of less than 400° C. The methods include depositing a silicon-containing precursor film using a plasma enhanced atomic layer deposition and treating the silicon-containing precursor film with an oxidizing agent to provide volumetric expansion of the silicon-containing precursor, providing a large area gap fill that is substantially free of voids and/or seams. Additionally, the volumetric expansion deposition process can form a large area gap fill of a silicon-based material that includes no cracking and is substantially free of defects. The method can also reduce the amount of precursor that is needed to perform the large area gap fill compared to conventional methods.

### EXAMPLES

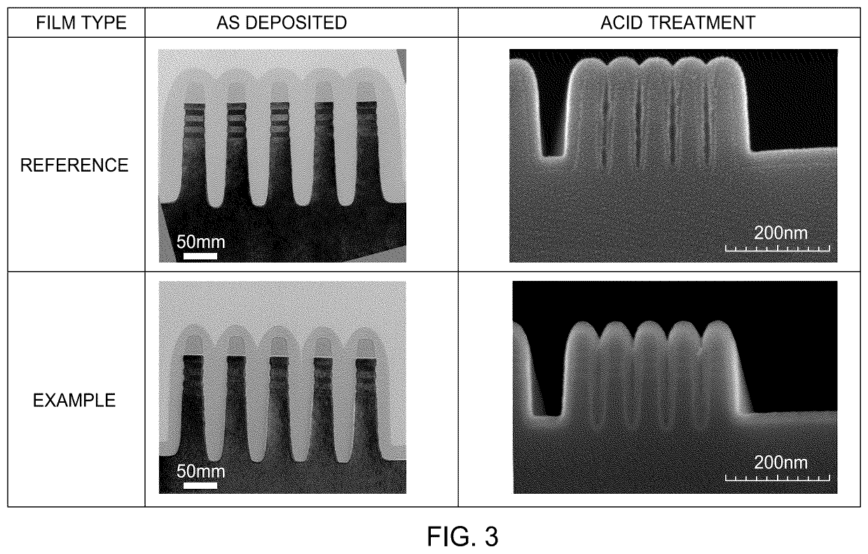

Now referring to FIG. 3, a substrate filled with an oxide gap fill material using a conventional plasma enhanced chemical vapor deposition process (e.g., reference) was compared to a substrate filled with an oxide gap fill material using a volumetric expansion deposition process described herein (e.g., example). The reference substrate and example substrate was produced and analyzed using transmission electron microscopy (TEM) to monitor the formation of a seam and/or void in the substrate. The reference substrate and example substrate were formed and subsequently treated with dilute hydrofluoric acid, e.g., 1:100 hydrofluoric acid in water, for 30 seconds. After 30 seconds the oxide gap fill material of the reference substrate formed a seam and/or void between the features of the substrate. After 30 seconds the oxide gap fill material of the example substrate resisted the formation of the seam, in which a smaller void formed in the example substrate as compared to the reference substrate.

While the foregoing is directed to embodiments of the present disclosure, other and further embodiments of the disclosure can be devised without departing from the basic scope thereof, and the scope thereof is determined by the claim that follows.

What is claimed is:

1. A method, the method comprising:
forming a precursor film by delivering a precursor to a substrate in a processing chamber having a high aspect ratio opening defining a gap between two or more features of the substrate;
forming an expansion film by treating the precursor film with a plasma; and
delivering an oxygen-containing compound to the expansion film to form an oxide gap fill material having a volume that is about 1.1 to about 2.0 greater than the expansion film.

2. The method of claim 1, wherein delivering the precursor to the substrate comprises maintaining a temperature of the processing chamber at about 350° C. to about 400° C.

3. The method of claim 1, wherein delivering the precursor to the substrate comprises delivering the precursor to the substrate for about 200 milliseconds (ms) to about 1200 ms.

4. The method of claim 1, wherein the precursor film comprises a thickness of about 1.5 Å to about 10 Å.

5. The method of claim 1, wherein treating the precursor film with the plasma comprises flowing a radical into the processing chamber.

6. The method of claim 1, wherein the radical comprises a C* or N*-containing radicals selected from the group consisting of C*, CN*, OCN*, N*, NH₃*, N₂H₄*, NH₂*, NH*, C₃H₆*, C₂H₂*, and combinations thereof.

7. The method of claim 1, wherein the expansion film comprises a silicon-containing compound.

8. The method of claim 7, wherein the silicon-containing compound is selected from the group consisting of silicon, silicon carbide, silicon carbon-nitride, silicon oxycarbonitride, silicon nitride, and combinations thereof.

9. The method of claim 1, wherein the expansion film comprises a Pilling-Bedworth ratio of about 1.0 to about 2.0.

10. The method of claim 1, further comprising filling a gap of the substrate with the oxide gap fil material.

11. The method of claim 1, wherein the oxygen-containing compound is selected from the group consisting of diatomic oxygen, ozone, peroxide, water, nitrous oxide, oxygen plasma, and combinations thereof.

12. A method, the method comprising:
forming a precursor film by delivering a precursor to a substrate in a processing chamber having a high aspect ratio opening defining a gap between two or more features of the substrate;
forming an expansion film by treating the precursor film with a plasma, wherein the plasma and the precursor are alternated cyclically to form the expansion film; and
delivering an oxygen-containing compound to the expansion film to form an oxide gap fill material having a volume that is about 1.1 to about 2.0 greater than the expansion film, wherein the oxygen-containing compound and the formation of the expansion film are alternated cyclically to form the oxide gap fill material.

13. The method of claim 12, wherein delivering the precursor to the substrate comprises maintaining a temperature of the processing chamber at about 350° C. to about 400° C.

14. The method of claim 12, wherein the precursor film comprises a thickness of about 1.5 Å to about 10 Å.

15. The method of claim 12, wherein treating the precursor film with the plasma comprises flowing a radical into the processing chamber.

16. The method of claim 12, wherein the radical comprises a C* or N*-containing radicals selected from the group consisting of C*, CN*, OCN*, N*, NH₃*, N₂H₄*, NH₂*, NH*, C₃H₆*, C₂H₂*, and combinations thereof.

17. The method of claim 12, wherein the expansion film comprises a silicon-containing compound selected from the group consisting of silicon, silicon carbide, silicon carbon-nitride, silicon oxycarbonitride, silicon nitride, and combinations thereof.

18. The method of claim 12, wherein the expansion film comprises a Pilling-Bedworth ratio of about 1.0 to about 2.0.

19. The method of claim 12, further comprising filling a gap of the substrate with the oxide gap fil material.

20. The method of claim 12, wherein the oxygen-containing compound is selected from the group consisting of diatomic oxygen, ozone, peroxide, water, nitrous oxide, oxygen plasma, and combinations thereof.
